(19) United States
(12) Patent Application Publication
(10) Pub. No.: US 2016/0268373 A1
(43) Pub. Date: Sep. 15, 2016

(54) SEMICONDUCTOR APPARATUS HAVING HEAT DISSIPATING FUNCTION AND ELECTRONIC EQUIPMENT COMPRISING SAME

(71) Applicant: SILICONFILE TECHNOLOGIES INC., Seongnam-si Gyeonggi-do (KR)

(72) Inventors: Min Suk KO, Gyeonggi-do (KR); Kyoung Sik PARK, Gyeonggi-do (KR); Gab Hwan CHO, Gyeonggi-do (KR); Heui Gyun AHN, Gyeonggi-do (KR); Sang Wook AHN, Gyeonggi-do (KR); Yong Woon LEE, Gyeonggi-do (KR); Huy Chan JUNG, Gyeonggi-do (KR)

(21) Appl. No.: 15/030,347

(22) PCT Filed: Oct. 2, 2014
(86) PCT No.: PCT/KR2014/009324

§ 371 Date: Apr. 18, 2016

(30) Foreign Application Priority Data
Oct. 17, 2013 (KR) 10-2013-0123817

(51) Int. Cl. H01L 29/06; H01L 27/146; H01L 23/373; H01L 23/367; H01L 23/467

(52) U.S. Cl. CPC H01L 29/0657; H01L 23/367; H01L 23/467; H01L 23/3736; H01L 27/14618

(57) ABSTRACT

A semiconductor apparatus having a heat dissipating function and electronic equipment comprising the same includes a front surface on which semiconductor devices constituting a circuit a circuit are formed; and a rear surface including a convexo-concave surface. Thus, the heat dissipation effect of the semiconductor apparatus can be maximized even without attaching a heat dissipation plate thereto.

### TECHNICAL FIELD

The present invention relates to a semiconductor apparatus, and more specifically, to a semiconductor apparatus having a heat dissipating function and electronic equipment comprising the same.

### BACKGROUND ART

As a market of electronic equipment, e.g., a portable device, has been developed, the portability side has been risen in prominence, and a thin device is notable to the market and is good response from consumers. Manufactures of the portable device have started the competition in the thickness of the portable device, and to make the portable device thinner may be widely known as a manufacture having an excellent technique. In order to manufacture the portable device thinner, the thickness of the parts of the portable device must be reduced.

An image sensor used for implementing a camera is one of devices attached to the portable device. Generally, the image sensor implements an image sensing circuit on a semiconductor substrate which is highly integrated.

Since a semiconductor device having electrical circuits on the semiconductor substrate has a small size and the electrical circuits are integrated, a heat is necessarily dissipated when an operation of the semiconductor device is performed. The dissipated heat may cause a malfunction of semiconductor elements formed on the semiconductor substrate. Thus, in order to dissipate the generated heat, a metal material may be attached to the semiconductor device, a dissipation plate of various types may be attached in case of the semiconductor device having a high performance such as a central processing unit (CPU), or a heat sink may be performed by adding a fan to the semiconductor device.

However, since the semiconductor device used in the portable device should be thin, a dissipation member such as the dissipation plate or the fan may not be attached to the semiconductor device used in the portable device, and in case of few portable device, the semiconductor device excluding the dissipation plate is used. Meanwhile, since the semiconductor device has a high performance is a highly integrated product, and has a small size, the performance of the semiconductor device may be often deteriorated due to the difficulties of removing the heat dissipated from the operation of the semiconductor device.

Thus, the needs for effectively dissipating the heat generated from the semiconductor device without attaching the dissipation member to the semiconductor device have been requested.

### DISCLOSURE

### Technical Problem

The present invention is directed to a semiconductor apparatus having a heat dissipating function without a dissipation instrument and electronic equipment comprising the same.

### Technical Solution

In accordance with an embodiment of the present invention, a semiconductor device may include a front side of a semiconductor substrate on which semiconductor elements are formed; and a back side of the semiconductor substrate having convexo-concave surfaces.

In accordance with an embodiment of the present invention, a semiconductor device may include a front side of a semiconductor substrate having semiconductor elements that constitute a circuit; a back side of the semiconductor substrate having convexo-concave surfaces; and a heat dissipation film formed on the convexo-concave surfaces among the convexo-concave surfaces, wherein an edge of

In accordance with an embodiment of the present invention, a semiconductor device may include a front side of a semiconductor substrate having semiconductor elements that constitute a circuit; a back side of the semiconductor substrate having convexo-concave surfaces; and a heat dissipation film formed on each of convex surfaces among the convexo-concave surfaces, wherein an edge of the heat dissipation film is wider than an edge of the convex surfaces.

In accordance with an embodiment of the present invention, a semiconductor device may include a front side of a semiconductor substrate having semiconductor elements that constitute a circuit; a back side of the semiconductor substrate having convexo-concave surfaces; and a heat dissipation film having a plurality of layers formed on each of convex surfaces among the convexo-concave surfaces, wherein edges of the heat dissipation film having the plurality of layers have alternately different area.

In accordance with an embodiment of the present invention, an electronic equipment may include a semiconductor device mounted on a side of the electronic equipment, wherein the semiconductor device comprises a front side of a semiconductor device having semiconductor elements that constitute a circuit; a back side of the semiconductor device having convexo-concave surfaces; and a plurality of fluid holes formed between the back side of the semiconductor device and the side of the electronic equipment, wherein an air is filed in the plurality of fluid holes, and a heat generated from the semiconductor device is dissipated to the air filled in the plurality of fluid holes.

### Advantageous Effects

The present invention may maximize a heat dissipation effect for dissipating a heat generated from a semiconductor device to the outside of the semiconductor device with only the semiconductor device and protect semiconductor elements formed in the semiconductor device by forming a convexo-concave surface on a rear side of the semiconductor device.

That is, the present invention may maximize the heat dissipation effect of the semiconductor device without attaching a dissipation plate to the semiconductor device.

By not attaching a heat dissipation plate to a semiconductor device, the thickness or the height of an electronic equipment having the semiconductor device is not increased, and thus, the electronic equipment may be manufactured to be thin.

Also, by not attaching the heat dissipation plate to a semiconductor device, a manufacturing cost of the electronic equipment having the semiconductor device is reduced, and the productivity of the electronic equipment is improved.

Also, by not attaching the heat dissipation plate, a manufacturing process of the electronic equipment having the electronic equipment is simplified, and the production yield of the electronic equipment is improved.

### DESCRIPTION OF DRAWINGS

FIG. 1 is a cross sectional view illustrating a semiconductor device in accordance with a first embodiment of the present invention.

FIG. 2 is perspective views illustrating a back side of the semiconductor device shown in FIG. 1.

FIG. 3 is a cross sectional view illustrating a semiconductor device in accordance with a second embodiment of the present invention.

FIG. 4 is a cross sectional view illustrating a semiconductor device in accordance with a third embodiment of the present invention.

FIG. 5 is a cross sectional view illustrating a semiconductor device in accordance with a fourth embodiment of the present invention.

FIG. 6 is a cross sectional view illustrating an electronic equipment having the semiconductor device shown in FIG. 1.

### BEST MODE

Hereinafter, various embodiments will be described below in more detail with reference to the accompanying drawings such that a skilled person in this art understand and implement the present invention easily.

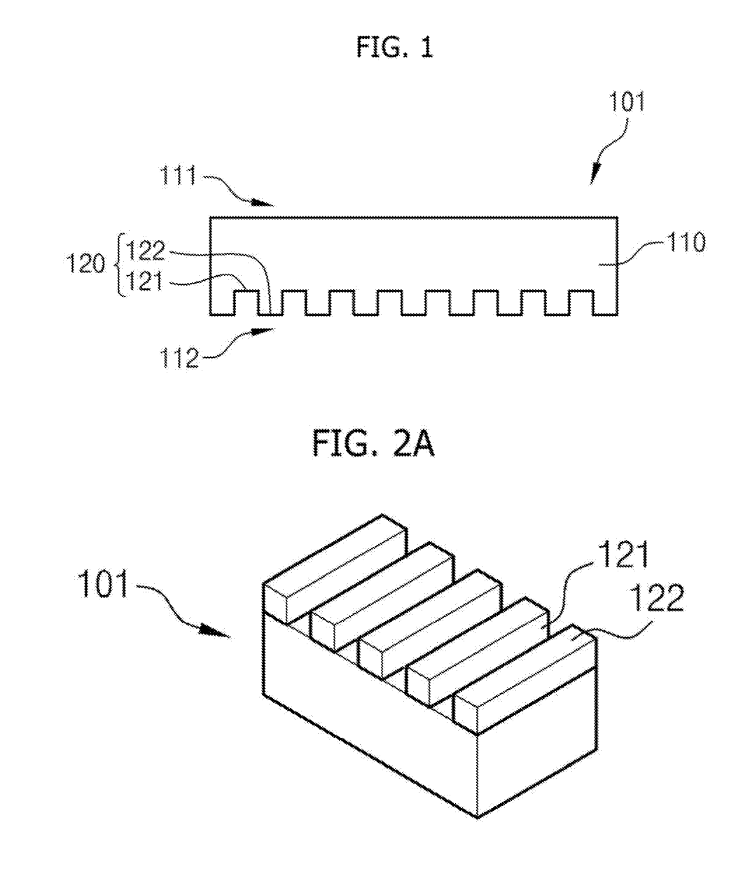

FIG. 1 is a cross sectional view illustrating a semiconductor device in accordance with a first embodiment: of the present invention. Referring to FIG. 1, a semiconductor device 101 includes a semiconductor substrate 110, semiconductor elements (not shown), which constitute circuits, are formed on a front side 111 of the semiconductor substrate 110, and a convexo-concave surface 120 is formed on a back side 112 of the semiconductor substrate 110 The convexo-concave surface 120 is formed on a side, i.e., a back side on which the semiconductor elements are not formed in the semiconductor substrate 110. A plurality of convex surfaces 122 and a plurality of concave surfaces 121 constitute the convexo-concave surface 120.

Like this, a cross sectional area of the back side 112 of the semiconductor device 101 increases greatly by forming a plurality of concave surfaces 121 on the back side 112 of the semiconductor device 101. An area of the back side 112 of the semiconductor device 101 which contacts with an air increases greatly due to the greatly increase of the cross sectional area.

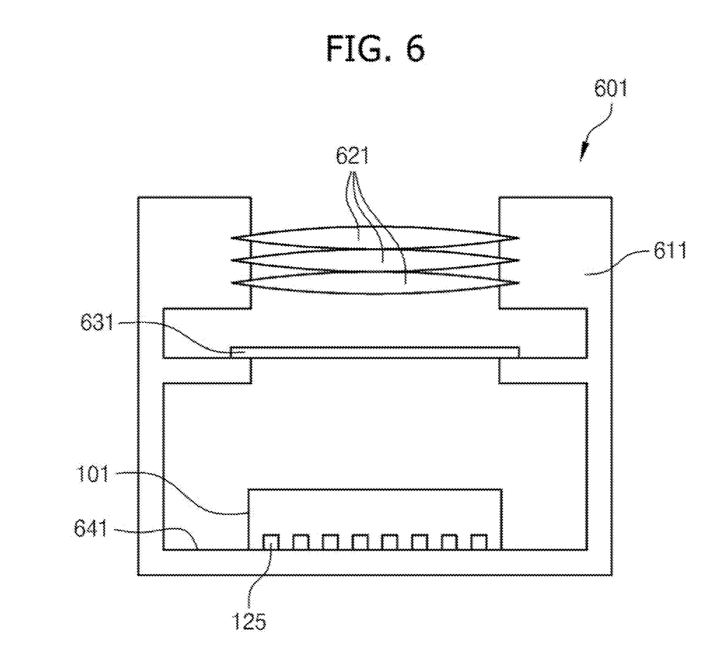

In a case that the semiconductor device 101 is mounted on a specific device, i.e., a camera 601 of FIG. 6 of a portable device, the plurality of concave surfaces 121 have a plurality of fluid holes 125 of FIG. 6 between the semiconductor device 101 and the specific device. More specifically, in case that the back side 112 having the convexo-concave surface 120 of the semiconductor device 101 is attached to a side 641 of FIG. 6 of the specific device, the plurality of fluid holes 125 of FIG. 6 are formed between the back side 112 of the semiconductor device 101 and the side of the specific device. The plurality of fluid holes 125 of FIG. 6 forms a path through which an air or a fluid passes. Thus, the air or fluid may pass the back side 112 of the semiconductor device 101 through the plurality of fluid holes 125 of FIG. 6.

If a power voltage is applied to the semiconductor elements formed on the front side 111 of the semiconductor device 101 from an external device, the semiconductor elements start an operation, and a heat is generated from the semiconductor device 101. The generated heat may cause a malfunction of the semiconductor elements. Thus, it is requested to rapidly dissipate the generated heat from the semiconductor device 101 to the outside of the semiconductor device 101. The greater the number of semiconductor elements is, the more heat is generated. Therefore, it is preferable that the number or the depth of the plurality of concave surfaces 121 which are formed on the back side of the semiconductor device 101 is properly adjusted according to the number or the performance of the semiconductor elements formed on the back side of the semiconductor device 101. For example, in case that the number of the semiconductor elements is great or a power consumption is great, the heat generated from the semiconductor device 101 may be rapidly dissipated by forming, the plurality of concave surfaces 121 deep and increasing the amount of air which passes through the plurality of concave surfaces 121.

As shown in FIG. 1, since the semiconductor device 101 according to the present invention has the plurality of concave surfaces 121 on the back side 112 of the semiconductor device 101, the heat is rapidly dissipated to the air which is full in the plurality of concave surfaces 121 in case that the heat is generated from the semiconductor device 101. Thus, the semiconductor elements formed on the semiconductor device 101 may operate stably without a malfunction.

Like this, by forming the convexo-concave surface 120 on a side, i.e., the back side 112 of the semiconductor device 101, on which circuits are not formed, the cross sectional area of the back side 112 of the semiconductor device 101 increases greatly, and an area where the back side 112 of the semiconductor device 101 contacts with the air increases greatly. Thus, in case that the semiconductor elements operate in the state that the semiconductor device 101 is mounted on the specific device, the heat generated from the semiconductor device 101 is rapidly dissipated to the air or the fluid through the plurality of fluid holes 125 of FIG. 6, and the semiconductor elements of the semiconductor device 101 operates stable without the malfunction.

The convexo-concave surface 120 of the back side of the semiconductor device 101 may be simply formed using a conventional manufacturing of a wafer having the plurality of semiconductor devices 101. For example, in order to form the convexo-concave surface 120 of the back side of the semiconductor device 101, a photoresist layer is formed on a surface of the back side 112 of the semiconductor substrate 110, the photoresist layer is patterned and then the semiconductor substrate 110 is etched using the patterned photoresist layer as a mask. Subsequently, if the photoresist layer remained on the back side of the semiconductor substrate 110 is removed, the convexo-concave surface 120 is formed on the back side 112 of the semiconductor device 101 as shown in FIG. 1.

In general, a patterning process of a photoresist layer includes a masking process for disposing a mask having a pattern of a specific shape on a photoresist layer, an exposure process for illuminating a light from an upper portion of the mask, and a development process for remaining the photoresist layer having the specific pattern by developing the exposed photoresist layer. This patterning process may be implemented by a general process technique.

Like this, there are no needs for adding a separate manufacturing process in order to form the convexo-concave surface 120 of the back side of the semiconductor device 101.

Furthermore, a conventional equipment used for manufacturing a wafer may be used as an equipment for forming the photoresist layer on the back side 112 of the semiconductor device 101, an equipment for patterning the photoresist layer, and an equipment for etching the semiconductor device 101.

Like this, there are no needs for adding a separate semiconductor manufacturing equipment in order to form the convexo-concave surface 120 of the back side of the semiconductor device 101.

In conclusion a manufacturing cost is nearly not increased in order to form the convexo-concave surface 120 of the back side of the semiconductor device 101.

As shown in FIG. 1, according to the present invention, a cross sectional area of the back side 112 of the semiconductor device 101 increases greatly by forming a plurality of concave surfaces 121 on the back side 112 of the semiconductor device 101 where circuits of the semiconductor device 10 are not formed. Thus, an area of the back side 112 of the semiconductor device 101 which contacts with an air increases greatly. If the area which contacts with the air increases, the heat dissipation effect of the semiconductor device is improved.

As described above, according to the present invention, the semiconductor device 101 has an excellent heat dissipation effect without any attachment.

Thus, the thickness or the depth of an electronic equipment having the semiconductor device is not lengthened, and as a result, a thin electronic equipment may be manufactured.

Also, a manufacturing cost of the electronic equipment having the semiconductor device 101 is reduced and the productivity of electronic equipment is improved by not attaching a conventional heat dissipation plate to the semiconductor device 101 and a production yield of the electronic equipment 101 is improved by simplifying the manufacturing process of the electronic equipment having the semiconductor device 101.

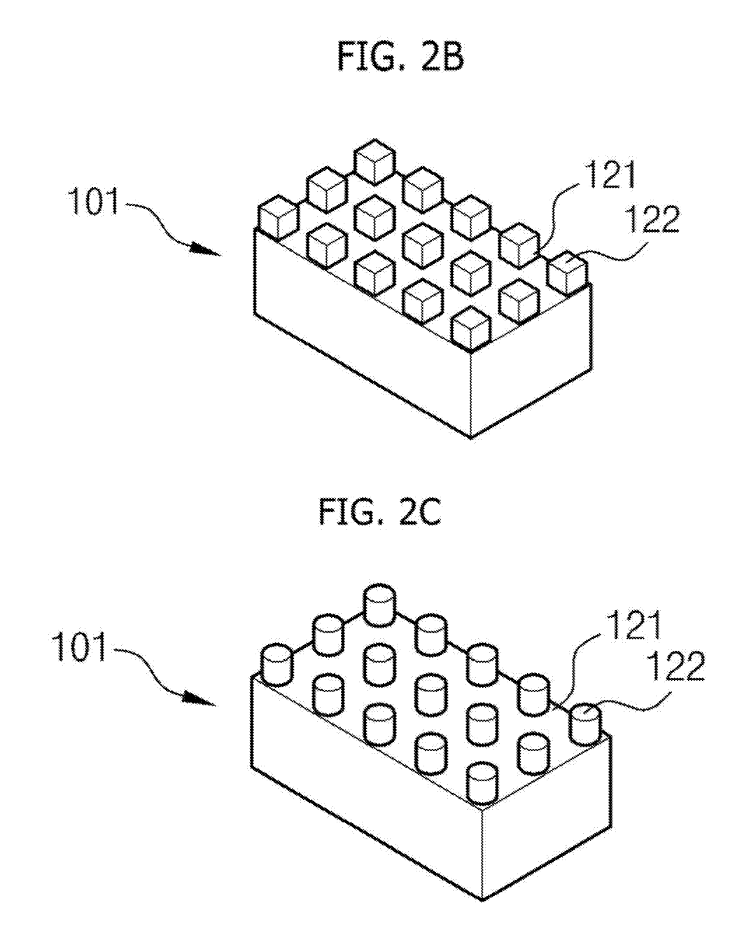

FIG. 2 is perspective views illustrating a back side of the semiconductor device shown in FIG. 1.

Referring to FIG. 2A a plurality of convex surfaces 122 of a rectangular parallelepiped shape and a plurality of long concave surfaces 121 formed between the plurality of convex surfaces 122 constitute the convexo-concave surface 120 of the semiconductor device 101.

Like this, the plurality of long concave surfaces 121 are formed between the plurality of convex surfaces 122 by forming the plurality of convex surfaces 122 of the rectangular parallelepiped shape on the back side 112 of the semiconductor device where circuits are not formed.

The cross sectional area of the back side 112 of the semiconductor device 101 increases greatly due to the plurality of convex surfaces 122 of the rectangular parallelepiped shape and the plurality of concave surfaces 121 formed between the plurality of convex surfaces 122. Thus, an area of the back side 112 of the semiconductor device 101, which is contacted with the air, is widened. If the area contacted with the air is widened, the dissipation speed of the heat generated from the semiconductor elements of the semiconductor device 101 increases greatly, and thus, the heat dissipation effect of the semiconductor device 101 is improved.

Referring to FIG. 2B, the plurality of convex surfaces 122 of a square pillar shape and spaces formed between the plurality of convex surfaces 122 of the square pillar shape constitute the convexo-concave surface 120 of the semiconductor device 101.

Like this, the spaces 122 are formed between the plurality of convex surfaces 122 of the square pillar shape by forming the plurality of convex surfaces 122 of the square pillar shape on the back side 112 of the semiconductor device 101 on which circuits of the semiconductor device 101 are not formed.

The cross sectional area of the back side 112 of the semiconductor device 101 increases greatly due to the plurality of convex surfaces 122 of the square pillar shape and the spaces therebetween. Thus, an area of the back side 112 of the semiconductor device 101, which is contacted with the air, is widened. If the area contacted with the air is widened, the dissipation speed of the heat generated from the semiconductor elements of the semiconductor device 101 increases greatly, and thus, the heat dissipation effect of the semiconductor device 101 is improved.

Referring to FIG. 2C, the plurality of convex surfaces 122 of a cylindrical shape and spaces formed between the plurality of convex surfaces 122 of the cylindrical shape constitute the convexo-concave surface 120 of the semiconductor device 101.

Like this, the spaces 122 are formed between the plurality of convex surfaces 122 of the cylindrical shape by forming the plurality of convex surfaces 122 of the cylindrical shape on the back side 112 of the semiconductor device 101 on which circuits of the semiconductor device 101 are not formed.

The cross sectional area of the back side 112 of the semiconductor device 101 increases greatly due to the plurality of convex surfaces 122 of the cylindrical shape and the spaces therebetween. Thus, an area of the back side 112 of the semiconductor device 101, which is contacted with the air, is widened. If the area contacted with the air is widened, the dissipation speed of the heat generated from the semiconductor elements of the semiconductor device 101 increases greatly, and thus, the heat dissipation effect of the semiconductor device 101 is improved.

The shape of the convex surfaces formed on the back side 112 of the semiconductor device 101 in accordance with the present invention may be changed into a various shape such as a triangular shape, a hexagonal shape, a star shape, and so on.

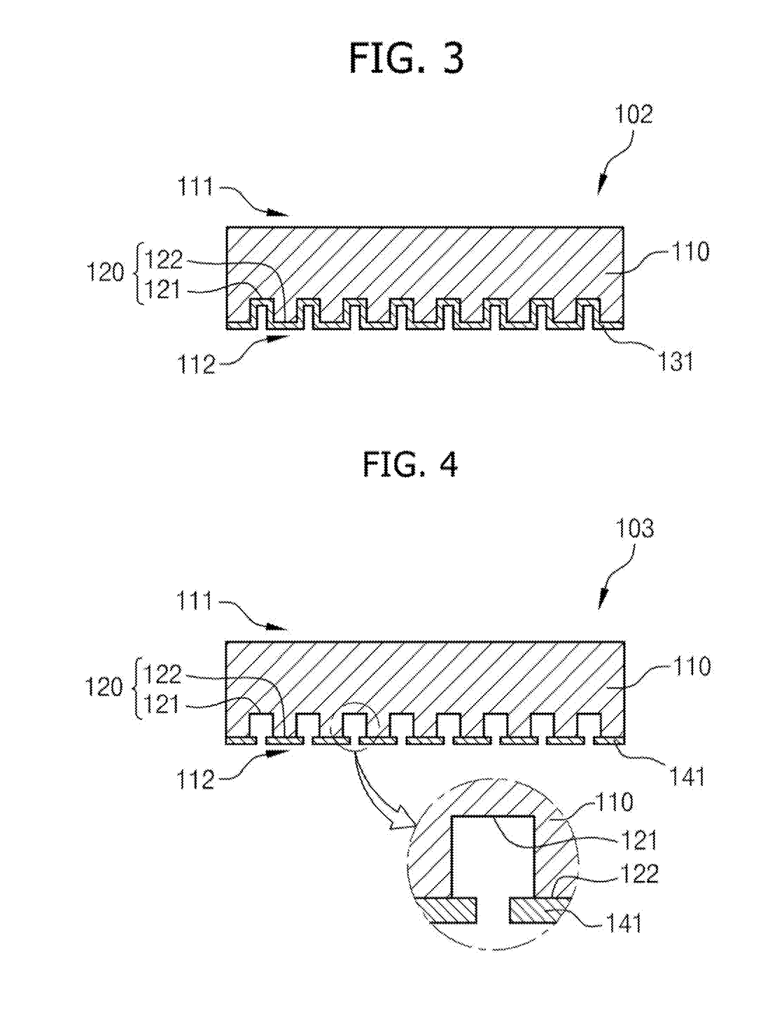

FIG. 3 is a cross sectional view illustrating a semiconductor device in accordance with a second embodiment of the present invention. Referring to FIG. 3, the semiconductor device 102 includes a semiconductor substrate 110, and semiconductor elements (not shown), which constitute circuits, are formed on the front side 111 of the semiconductor substrate 110. The convexo-concave surface 120 is formed on the back side 112 of the semiconductor substrate 110, i.e., a side on which the semiconductor elements are not formed. Also, a heat dissipation film 131 having an excellent thermal conductivity, i.e., a metal, a carbon fiber, a graphite, a ceramic, a plastic, and so on, is formed on the convexo-concave surfaces 120.

A structure of the semiconductor substrate 110 and a manufacturing method thereof are omitted since the structure of the semiconductor substrate 110 and a manufacturing method thereof is same as the semiconductor substrate 110 described with reference to FIG. 1.

As shown in FIG. 3, since the convexo-concave surface 120 is formed on the back side 112 of the semiconductor device 101 on which circuits are not formed, and the heat dissipation film 131 having the excellent thermal conductivity is formed on the convexo-concave surface 120, the cross sectional area of the back side 112 of the semiconductor device 102, which is contacted with the air, increases greatly. If the area contacted with the air is widened, the dissipation speed of the heat generated from the semiconductor elements of the semiconductor device 101 increases greatly.

Also, by forming the heat dissipation film 131 having the excellent thermal conductivity on the convexo-concave surface 120, the heat generated from the semiconductor device 101 is more rapidly dissipated to the outside through the heat dissipation film 131.

Like this, the heat dissipation effect of the semiconductor 102 is remarkably improved by forming the convexo-concave surface 120 on the back side 112 of the semiconductor substrate 110 on which the semiconductor elements are not formed and by forming the heat dissipation film 131 having the excellent thermal conductivity on the convexo-concave surface 120.

As described above, in accordance with the second embodiment of the present invention, the heat dissipation of the semiconductor device 102 is improved and it is not requested to attach a conventional heat dissipation plate to the semiconductor device 102.

Thus, the thickness or the height of the electronic equipment having the semiconductor device 102 is not increased, and thus, the electronic equipment may be maintained to be thin.

Moreover, by not attaching the conventional heat dissipation plate to the semiconductor device 102, a manufacturing cost of the electronic equipment having the semiconductor device 102 is reduced, the productivity of the electronic equipment is improved greatly, a manufacturing process of the electronic equipment having the semiconductor device 102 is simplified, and the production yield of the electronic equipment is improved.

The convex-concave surface 120 of the semiconductor device 102 shown in FIG. 3 may include a plurality of convex surfaces 122 of a rectangular parallelepiped shape and a plurality of long concave surfaces 121 formed between the plurality of convex surfaces 122 of the rectangular parallelepiped as shown in FIG. 2A, include a plurality of convex surfaces 122 of a square pillar shape and spaces 121 formed between the plurality of convex surfaces 122 of the square pillar shape as shown in FIG. 2B, or include a plurality of convex surfaces 122 of a cylindrical shape and spaces formed between the plurality of convex surfaces 122 of the cylindrical shape as shown in FIG. 2C.

FIG. 4 is a cross sectional view illustrating a semiconductor device in accordance with a third embodiment of the present invention. Referring to FIG. 4, the semiconductor device 103 includes a semiconductor substrate 110, a front side 111 of the semiconductor substrate 110 has semiconductor elements (not shown) which constitute circuits, and a back side 112 of the semiconductor substrate 110 has a convexo-concave surface 120. The convexo-concave surface 120 is formed on a side, i.e., the back side 112 on which the semiconductor elements are not formed among the semiconductor substrate 110.

A structure of the semiconductor substrate 110 and a manufacturing method thereof are omitted since the structure of the semiconductor substrate 110 and a manufacturing method thereof is same as the semiconductor substrate 110 described with reference to FIG. 1.

As shown in FIG. 3 a heat dissipation film 141 is formed on each of the convex surfaces 122 among the convexo-concave surfaces 120 of the semiconductor device 103, an edge of the heat dissipation film 141 is formed wider than an edge of the convex surfaces 122. Herein, it is preferable that the heat dissipation film 141 includes a material having an excellent thermal conductivity, i.e., a metal, a carbon fiber, a graphite, a ceramic, a plastic and so on.

Like this, by forming the convexo-concave surface 120 on the back side 112 of the semiconductor substrate 110 on which the semiconductor elements of the semiconductor device 103 are not formed, by forming the heat dissipation film 141 on each of the convex surfaces 122 among the convexo-concave surfaces 120, and by forming the edge of the heat dissipation film 141 wider than the edge of the convex surfaces 122, the cross sectional area of the back side 112 of the semiconductor device 103 increases greatly, and the area of the back side of the semiconductor device 103, which is contacted with the air, increases greatly.

Thus, the heat dissipation effect of the semiconductor device 103 is maximized. As a result, it is not necessary to attach a conventional heat dissipation plate to the semiconductor device 103.

As described above, in accordance with the third embodiment of the present invention, the heat dissipation effect, of the semiconductor device 103 may be maximized without attaching the conventional heat dissipation plate to the semiconductor device 103.

Thus, the thickness or the height of the electronic equipment having the semiconductor device 103 is not increased, and as a result, the electronic equipment may be maintained to be thin.

Moreover, by not attaching the conventional heat dissipation plate to the semiconductor device 103, a manufacturing cost of the electronic equipment having the semiconductor device 103 is reduced, the productivity of the electronic equipment is improved greatly, a manufacturing process of the electronic equipment having the semiconductor device 103 is simplified and the production yield of the electronic equipment is improved.

The convexo-concave surfaces 120 of the semiconductor device 103 shown in FIG. 4 may include a plurality of convex surfaces 122 of a rectangular parallelepiped shape and a plurality of long concave surfaces 121 formed between the plurality of convex surfaces 122 of the rectangular parallelepiped shape as shown in FIG. 2A, include a plurality of convex surfaces 122 of a square pillar shape and spaces 121 formed between the plurality of convex surfaces 122 of the square pillar shape as shown in FIG. 28, or include a plurality of convex surfaces 122 of a cylindrical shape and spaces formed between the plurality of convex surfaces 122 of the cylindrical shape as shown in FIG. 2C.

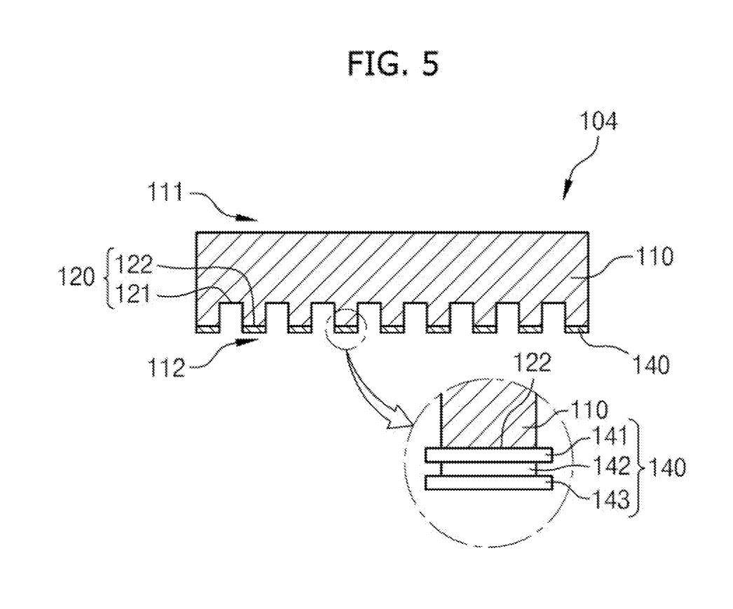

FIG. 5 is a cross sectional view illustrating a semiconductor device 104 in accordance with a fourth embodiment of the present invention. Referring to FIG. 5, the semiconductor device 104 includes a semiconductor substrate 110, semiconductor elements (not shown), which constitute circuits, are formed on a front side 111 of the semiconductor substrate 110 and are not formed on a back side 112 of the semiconductor substrate 110, which has a convexo-concave surface 120. That is, the convexo-concave surface 120 is formed on a side on which the semiconductor elements are not formed among the semiconductor substrate 110.

A structure of the semiconductor substrate 110 and a manufacturing method thereof are omitted since the structure of the semiconductor substrate 110 and a manufacturing method thereof is same as the semiconductor substrate 110 described with reference to FIG. 1.

A heat dissipation film 140 having a plurality of layers is formed on each of the plurality of convex surfaces 122 among the convexo-concave surfaces 122, and edges of the heat dissipation film 140 having the plurality of layers are alternately formed to have a different width. Herein, it is preferable that the heat dissipation film. 140 includes a material having an excellent thermal conductivity, i.e., a metal, a carbon fiber, a graphite, a ceramic, a plastic and so on.

Like this, by forming the convexo-concave surface 120 on the back side 112 of the semiconductor substrate 110 on which the semiconductor elements of the semiconductor device 104 are not formed, by forming the heat dissipation film 140 having the plurality of layers on each of the convex surfaces among the convexo-concave surfaces 120, and by alternately forming the edge of the heat dissipation film 140 having the plurality of layers to have different width, the cross sectional area of the back side 112 of the semiconductor device 104 increases greatly, and the area of the back side of the semiconductor device 104, which is contacted with the air, increases greatly.

Thus, the heat dissipation effect of the semiconductor device 104 is maximized. As a result, it is not necessary to attach a conventional heat dissipation plate to the semiconductor device 104.

As described above, in accordance with the fourth embodiment of the present invention, the heat dissipation effect of the semiconductor device 104 may be maximized without attaching a conventional heat dissipation plate to the semiconductor device 104.

Thus, the thickness or the height of the electronic equipment having the semiconductor device 104 is not increased, and as a result, the electronic equipment may be maintained to be thin.

Moreover, by not attaching the conventional heat dissipation plate to the semiconductor device 104, a manufacturing cost of the electronic equipment having the semiconductor device 104 is reduced, the productivity of the electronic equipment is improved greatly, a manufacturing process of the electronic equipment having the semiconductor device 104 is simplified and the production yield of the electronic equipment is improved.

The convexo-concave surfaces 120 of the semiconductor device 104 shown in FIG. 5 may include a plurality of convex surfaces 122 of a rectangular parallelepiped shape and a plurality of long concave surfaces 121 formed between the plurality of convex surfaces 122 of the rectangular parallelepiped shape as shown in FIG. 2A, include a plurality of convex surfaces 122 of a square pillar shape and spaces 121 formed between the plurality of convex surfaces 122 of the square pillar shape as shown in FIG. 2B, or include a plurality of convex surfaces 122 of a cylindrical shape and spaces formed between the plurality of convex surfaces 122 of the cylindrical shape as shown in FIG. 2C.

FIG. 6 is a cross sectional view illustrating an electronic equipment having the semiconductor device shown in FIG. 1. Referring to FIG. 6, an electronic equipment 601, i.e., an optical module 601 includes a body 611, an optical system 621 mounted on an upper portion of the body 611, a color filter 631 formed below the optical system 621, and an it age sensor 101 formed below the color filter 631.

The light which is incident from the outside reaches the image sensor 101 through the optical system 621 and the color filter 631. Herein, the color filter 631 blocks an infrared ray included in the light, and passes only a visible ray. Thus, the image sensor 101 may detect correctly an image received through the optical system 621.

The image sensor 101 may be implemented using any one of the semiconductor devices 101 to 104 shown in FIG. 1 and FIGS. 3 to 5.

If the image sensor 101 is mounted on a plane, i.e., a bottom plane 641 of the inside of the body 641, a plurality of fluid holes 125 are formed between the image sensor 101 and the bottom plane 641. An air or fluid passes through the plurality of fluid holes 125.

Thus, while the optical module operates, if the heat is generated from the image sensor 101, the generated heat is dissipated to the air or the fluid through the plurality of fluid holes 125. As a result, the image sensor 101 has not influenced on the heat, and operates stably.

Like this, since a heat dissipation effect of the image sensor is improved by itself, the conventional heat dissipation plate does not need to be attached to the image sensor 101.

Thus, the thickness or the height of the optical module 601 is not lengthened, and as a result, the optical module 601 may be manufactured to be thin.

Moreover, by not attaching the conventional heat dissipation plate to the image sensor 101, the manufacturing cost of the optical module 601 having the image sensor 101 is reduced, the productivity of the optical module 601 is improved greatly, a manufacturing process of the optical module 601 having the semiconductor device 104 is simplified, and the production yield of the optical module 601 is improved.

Although various embodiments have been described for illustrative purposes, it will be apparent to those skilled in the art that various changes and modifications may be made without departing from the spirit and scope of the invention as defined in the following claims.

What is claimed is:

1. A semiconductor device, comprising:
a front side of a semiconductor substrate on which semiconductor elements are formed; and
a back side of the semiconductor substrate having convexo-concave surfaces.

2. The semiconductor device of claim 1, wherein a convex surface among the convexo-concave surfaces has a rectangular parallelepiped shape.

3. The semiconductor device of claim 1, wherein a convex surfaces among the convexo-concave surfaces has a square pillar shape.

4. The semiconductor device of claim 1, wherein a convex surface among the convexo-concave surfaces has a cylindrical shape.

5. A semiconductor device comprising:
a front side of a semiconductor substrate having semiconductor elements that constitute a circuit;
a back side of the semiconductor substrate having convexo-concave surfaces; and
a heat dissipation film formed on the convexo-concave surfaces.

6. The semiconductor device of claim 5, wherein the heat dissipation film includes a metal having an excellent thermal conductivity.

7. A semiconductor device, comprising:
a front side of a semiconductor substrate having semiconductor elements that constitute a circuit;
a back side of the semiconductor substrate having convexo-concave surfaces; and
a heat dissipation film formed on each of convex surfaces among the convexo-concave surfaces,
wherein an edge of the heat dissipation film is wider than an edge of the convex surfaces.

8. The semiconductor device of claim 7, wherein the heat dissipation film includes a metal having an excellent thermal conductivity.

9. A semiconductor device, comprising:
a front side of a semiconductor substrate having semiconductor elements that constitute a circuit;
a back side of the semiconductor substrate having convexo-concave surfaces; and
a heat dissipation film having a plurality of layers formed on each of convex surfaces among the convexo-concave surfaces,
wherein edges of the heat dissipation film having the plurality of layers have alternately different area.

10. The semiconductor device of claim 9, wherein the heat dissipation film includes a metal having an excellent thermal conductivity.

11. An electronic equipment, comprising:
a semiconductor device mounted on a side of the electronic equipment,
wherein the semiconductor device comprises
a front side of a semiconductor device having semiconductor elements that constitute a circuit;
a back side of the semiconductor device having convexo-concave surfaces; and
a plurality of fluid holes formed between the back side of the semiconductor device and the side of the electronic equipment,
wherein an air is filed in the plurality of fluid holes, and a heat generated from the semiconductor device is dissipated to the air filled in the plurality of fluid holes.
